(19) United States
(12) Patent Application Publication
(10) Pub. No.: US 2025/0081397 A1
(43) Pub. Date: Mar. 6, 2025

(54) Integrated Vapor Chamber for Electronic Devices

(71) Applicant: Google LLC, Mountain View, CA (US)

(72) Inventors: Eric Chuang, New Taipei City (TW); Victor Cheng, New Taipei City (TW); Cheng-Lin Wang, Wujie Township (TW)

(73) Assignee: Google LLC, Mountain View, CA (US)

(21) Appl. No.: 18/934,562

(22) Filed: Nov. 1, 2024

Related U.S. Application Data
(60) Provisional application No. 63/714,000, filed on Oct. 30, 2024.

(51) Int. Cl. H05K 7/20; H04M 1/02

(52) U.S. Cl. CPC H05K 7/20309; H04M 1/0283; H05K 7/20318; H05K 7/20336

(57) ABSTRACT

This document describes a vapor chamber within an electronic device. In aspects, an electronic device includes a middle frame that provides mechanical support for the electronic device, a middle plate affixed to the middle frame to define an inner layer of a chassis, and a vapor chamber disposed inside the middle plate. The vapor chamber includes a first region proximate to a heat source and a second region opposite the first region. A coolant is evaporated in a first mode at the first region by heat absorbed from the heat source and is condensed in a second mode in the second region. This vapor chamber permits cooling of elements within the electronic device at lower cost and/or smaller size than many conventional cooling systems.

### CROSS-REFERENCE TO RELATED APPLICATION(S)

This application claims the benefit of U.S. Provisional Patent Application Ser. No. 63/714,000 filed on Oct. 30, 2024, the disclosure of which is incorporated by reference herein in its entirety.

### SUMMARY

This document describes techniques, systems, and apparatuses for integrating a vapor chamber within a middle plate of an electronic device. In some cases this integrated vapor chamber reduces a total thickness of the electronic device. In aspects, the electronic device includes a middle frame extending along at least two opposed edges, the middle frame configured to provide mechanical support for the electronic device. A middle plate is affixed to the middle frame to define an inner layer of a chassis. A vapor chamber is disposed inside the middle plate, the vapor chamber being configured to include a first region proximate to a heat source, a second region opposite the first region, and a coolant, which in a first mode of operation is configured to be evaporated at the first region by heat absorbed from the heat source, and which in a second mode of operation is configured to be condensed in the second region. The vapor chamber further includes a coolant transmission material that transmits the condensed coolant from the second region to the first region.

In some cases, the middle plate includes a top cover and a base member configured to encase the vapor chamber where the top cover includes a plurality of support pins configured to fixedly constrain the coolant transmission material. In this example, the coolant transmission material is a wick and the vapor chamber includes a vapor cavity that transports, in the first mode, the evaporated coolant from the first region to the second region.

The middle frame and middle plate may form a chassis that is configured to encase electronic device components. The middle plate is made of a high thermal conductivity metal material, e.g., stainless steel or titanium, and has a total thickness of the middle plate between 0.3 and 0.35 mm. The middle frame and the middle plate can be affixed together, such as with a plastic material via nano injection molding.

This Summary is provided to introduce simplified concepts for an integrated vapor chamber within an electronic device, which is further described below in the Detailed Description and is illustrated in the Drawings. This Summary is intended neither to identify essential features of the claimed subject matter nor for use in determining the scope of the claimed subject matter.

### BRIEF DESCRIPTION OF THE DRAWINGS

The details of one or more aspects of an integrated vapor chamber within an electronic device are described in this document with reference to the following drawings. The use of the same numbers in different instances may indicate similar features or components:

FIG. 1 depicts an exploded view of an example electronic device having a chassis.

FIG. 2 depicts an example middle frame of an electronic device.

FIG. 3 and FIG. 3A depict an example middle plate of an electronic device and a cross section of the middle plate, respectively.

FIG. 4 depicts an example a chassis of an electronic device.

FIG. 5 and FIG. 5A depict an example chassis of an electronic device and a cross section through a portion of the example chassis including a middle frame, respectively.

FIG. 6 depicts an example device diagram of example electronic devices in which a vapor chamber can be implemented.

### DETAILED DESCRIPTION

### Overview

Portable electronic devices such as smartphones and laptops have become an essential tool for consumers, providing communication and access to information and entertainment in a single device. Once considered a luxury, electronic devices have gradually evolved from bulky unreliable gadgets with a few features to powerful instruments that fit comfortably in tiny spaces. The drive to improve the design of electronic device has led to technological advancements such as increased processing power, advanced cameras, and high-quality screens. Components that enable these advancements, however, often generate heat that can damage the electronic device or themselves. This heat may be dissipated by employing thermal management components but these thermal management components often increase the thickness and cost of electronic devices.

More specifically, making electronic devices thinner without sacrificing device performance is a complex task that has hitherto not been fully resolved. For example, a printed circuit board (PCB) of a smartphone may include one or more processing elements with miniaturized components that attempt to reduce the size and thus, the overall thickness of the smartphone. The resulting smaller form factor, however, can produce a noticeable lack of internal space that not only increases the importance of thermal management components but also creates new difficulties for thermal management. As electronic devices incorporate powerful processors and high-performance components into smaller spaces, thermal management becomes a component of the design. Operations such as running applications and streaming videos produce heat which may be dissipated with components such as heat sinks, thermal conductive materials, and graphene sheets.

Some thermal management components, such as heat sinks, heat pipes, or liquid cooling structures may be employed but these components increase the size and weight of a smartphone. Even if they are relatively small, use of solder paste or other adhesives to adhere them to the heat-producing element, such as a PCB, also increase the size and weight of the smartphone.

To this end, the illustrative examples disclose improving thermal management and structural integrity for electronic devices by embedding a vapor chamber in a high-thermal-conductivity middle plate. More specifically, the illustrative examples disclose integrating thermal management components into the structural design of electronic devices. A chassis including a middle frame and a middle plate provides effective heat dissipation and structural support. The middle plate, made of high heat conductivity metals, may be stamped to produce a large vapor chamber area. The vapor chamber includes a coolant that goes through phase changes to move heat away from electronic components, while maintaining a slim profile.

Techniques and systems described herein make use of Nano Molding Technology (NMT) to integrate the middle frame and middle plate into a single structure that can support mechanical and thermal functions. To help condensed coolant return to the heat source through capillary action, the vapor chamber has a coolant transmission medium, like a wick. The vapor chamber's support pins preserve structural integrity and guard against collapse. By addressing heat dissipation in increasingly powerful and compact electronic devices as discussed herein, the overall thickness, weight, and/or cost of such systems can be improved.

The following discussion describes operating environments and techniques that may be employed in the operating environments and example methods. Although systems and techniques directed at an integrated vapor chamber for electronic devices are described, it is to be understood that the subject of the appended Claims is not necessarily limited to the specific features or methods described. Rather, the specific features and methods are disclosed as example implementations and reference is made to the operating environment by way of example only.

### Example Environment

The following discussion describes operating environments and techniques that may be employed in the operating environments and example methods. Although systems and techniques directed at an integrated vapor chamber for electronic devices are described, it is to be understood that the subject of the appended Claims is not necessarily limited to the specific features or methods described. Rather, the specific features and methods are disclosed as example implementations and reference is made to the operating environment by way of example only.

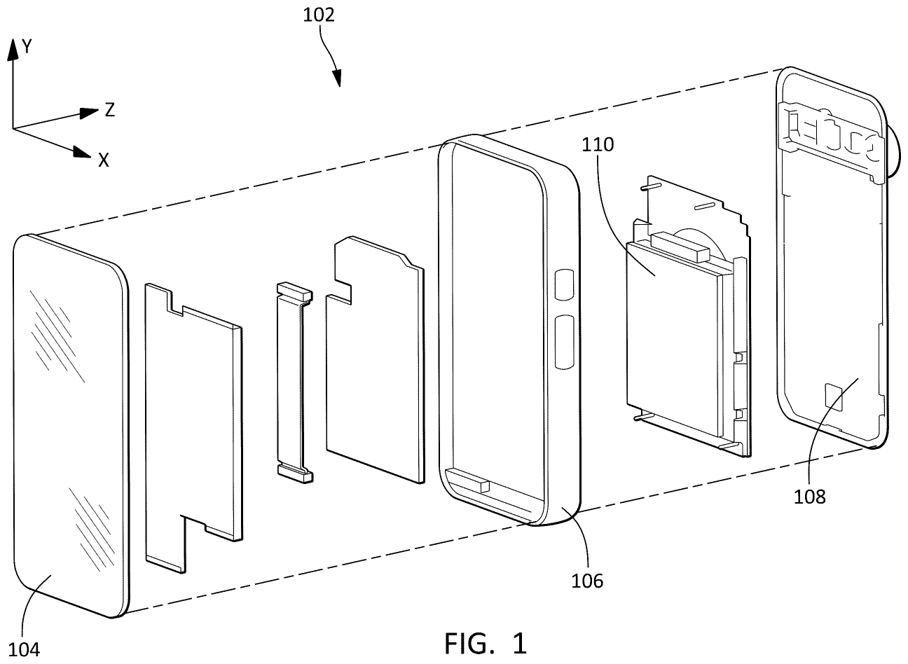

FIG. 1 illustrates an exploded view of an example implementation of an electronic device 102 (e.g., a smartphone) having a display 104, a chassis 106, a housing 108, and a battery 110. The display 104 may be implemented as a display panel stack having a cover layer and a display panel module. In at least some implementations, an opaque border is added to an underside of the cover layer, defining an active area of the display 104. Alternatively, the chassis 106 surrounding the display 104, defines the active area. The display 104 may further include one or more of a touch layer (e.g., touch sensor panel), a polarizer layer (e.g., polarization filters), an adhesive layer, and/or a protective layer. The protective layer may include one or more sublayers, such as a polymer sublayer (e.g., polyethylene terephthalate (PET) substrate, polyimide (PI), polycarbonate (PC), carbon fiber), a metallic sublayer (e.g., copper, stainless steel, titanium), a foam pad (e.g., to absorb compressive forces during manufacturing or usage), and an adhesive sublayer. The protective layer can shield the display panel module from mechanical and electromagnetic forces, as well as from thermal radiation.

As illustrated in the figure, the housing panel 108 is positioned on a first side of the chassis 106 opposite a second side where the display 104 is positioned. The chassis 106 comprises a middle frame and a middle plate and is configured to include an integrated vapor chamber to improve a volumetric efficiency inside the electronic device 102 and enable a thickness (e.g., in the Z-axis) of the electronic device 102 to be reduced.

In some implementations, the electronic device 102 houses the battery 110 (e.g., a rechargeable battery) and a wireless-charging coil within the internal electronic device 102. In some implementations, an outer enclosure of the electronic device 102 comprises a middle frame of the chassis 106, the display 104, and one or more housing panels 108.

The one or more housing panels may be metal, plastic, glass, or a composite and may include two or more layers of these materials stacked together. For example, a first layer of the housing panel 108 may comprise aluminum and a second layer of the housing panel 108 may comprise glass. The aluminum and glass may in some implementations include a through-cut for an elevated camera bar. Further, the one or more housing panels can be attached to the chassis 106 on at least one side of the chassis 106 (e.g., a frontside, a backside). For example, the one or more housing panels 108 include a back panel attached to the chassis 106 opposite the display 104.

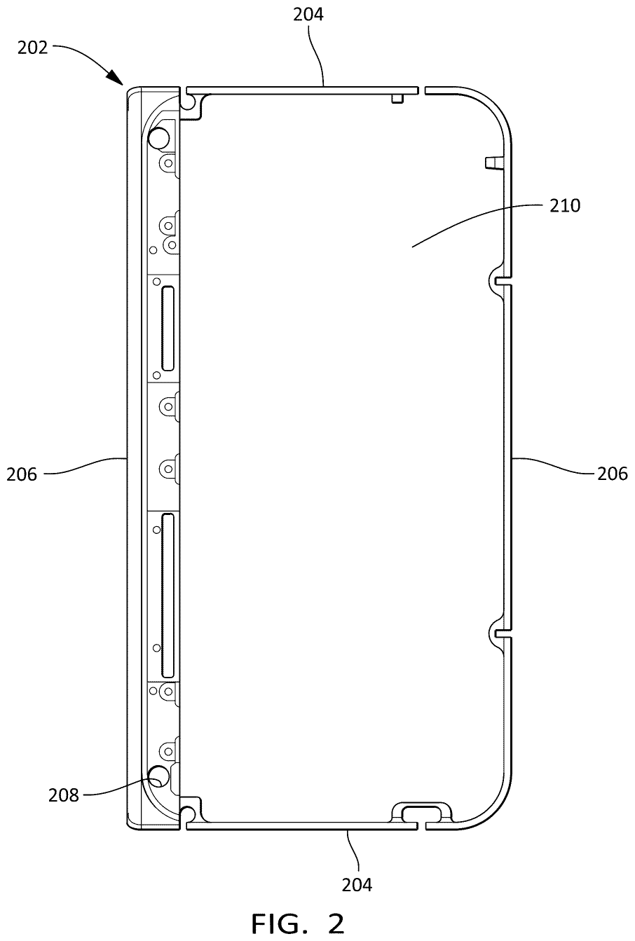

FIG. 2 discloses a middle frame 202 in accordance with an illustrative example. The middle frame 202 may form the structural skeleton of the electronic device 102 such as the visible outer edges of the chassis 106 (shown in FIG. 1). The middle frame 202 can hold and connect several components of the electronic device 102 (e.g., the display 104, the battery 110, and internal circuitry). The middle frame 202 comprises at least two opposed edges, including first opposed edges 204 and second opposed edges 206. The first opposed edges 204 may be perpendicular to the second opposed edges 206. The middle frame 202 is configured to provide strength and rigidity to the electronic device 102 and therefore aid in protecting internal components from damage caused by external forces. The middle frame 202 can be made from a metal such as aluminum or stainless steel and can include mounting points 208 for mounting other components of the electronic device 102, such as a motherboard, camera module, and buttons. In some cases, the middle frame 202 is a unibody material. The middle frame 202 may also be configured to enhance the appearance of the electronic device 102. For example, the metal shell is not only designed to have a good appearance but may also provide a delicate shape and texture for holding, wear resistance, falling resistance, corrosion resistance, and easy recycling. The middle frame 202 may comprise a smooth outer surface and a complex inner structure and may be formed by CNC (computer numerical control) cutting, drilling, and milling.

As illustrated in FIGS. 1 and 2, an outer enclosure of the electronic device 102 may include the middle frame 202 of the chassis 106, the display 104 and one or more housing panels 108, which may be attached to (e.g., adhered to, fastened to) the middle frame 202. In some implementations, the chassis 106 is manufactured (e.g., stamped, machined) with a through-cut 210 that is sized greater than or equal to a cross-sectional area of a middle plate to be affixed to the middle frame 202. By utilizing a large through-cut 210, less extrusion material (e.g., aluminum) may be used and manufacturing costs and device weight correspondingly reduced. In addition, the middle frame 202 with the large through-cut 204 may not contribute to a thickness for significant portions of the electronic device 102. As explained in greater detail below, a middle plate with an embedded vapor chamber enables the middle frame 202 to have such a large through-cut 210 to accommodate the middle plate.

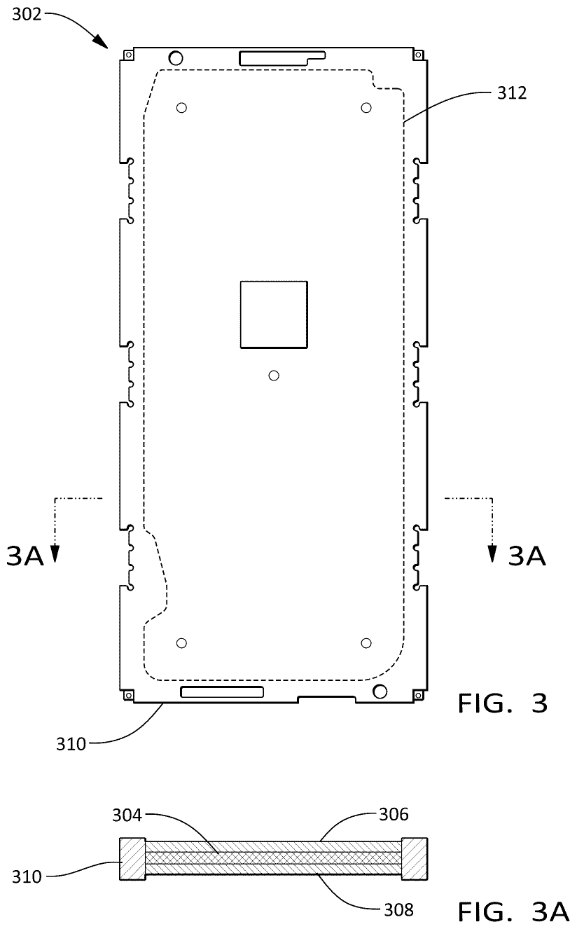

FIG. 3 illustrates a top view of a middle plate 302 along with a cross section. FIG. 3A shows the cross section of the middle plate 302, namely a vapor chamber 304, a top cover 306, a base member 308, and clamping structures 310. The middle plate 302 as shown in FIG. 3 also shows the clamping structures 310 and a vapor chamber area 312. The middle plate 302 may be a planar structure within which is embedded the vapor chamber 304 an area of which is designated with dashed lines as the vapor chamber area 312 for illustration purposes.

As shown in the cross-section 3A, the middle plate 302 includes the top cover 306 and the base member 308, which together encase the vapor chamber 304. The clamping structures 310 may be used to clamp or seal the top cover 306 and the base member 308 to isolate the vapor chamber 304 from the external environment. The middle plate 302 is made of a high thermal conductivity metal material such as stainless steel or titanium, which helps to quickly dissipate heat.

Integrating the vapor chamber in the middle plate 302 provides a heat-dissipation channel that can enable the electronic device 102 to be thinner by conserving volume from nesting the vapor chamber 304 and middle plate 302 inside the middle frame 202. Further, the area available for thermal dissipation is significantly increased by making use of the continuous available space along the X-Y plane.

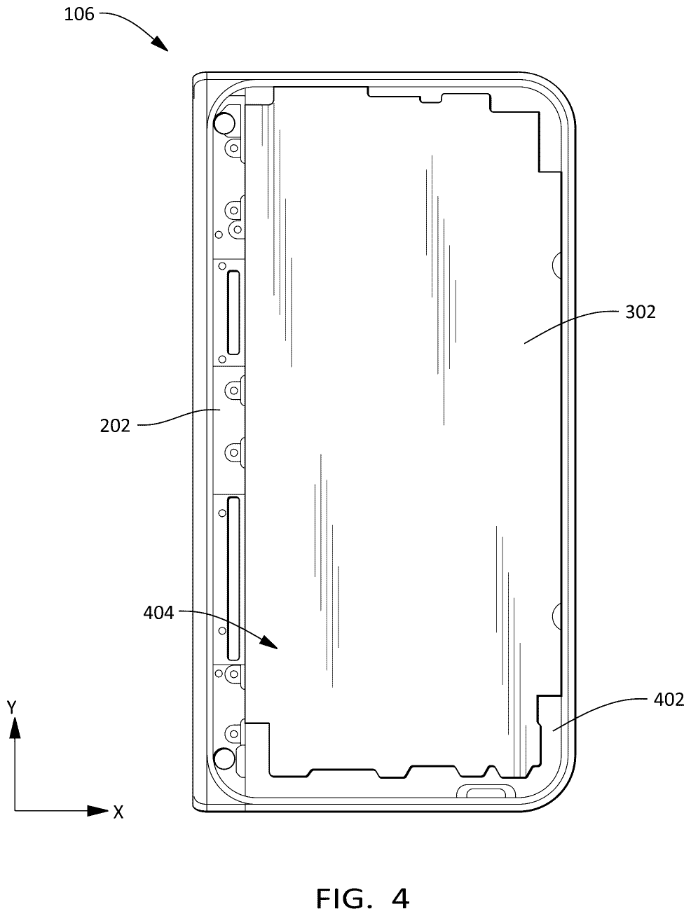

As illustrated in FIG. 4, which includes a plastic material 402 and an inner layer 404, the middle plate 302 may be affixed to the middle frame 202 to generate the chassis 106. The middle plate 302 therefore defines the inner layer 404 of the chassis 106. One way of affixing the middle plate 302 to the middle frame 202 is by NMT. For example, as shown, the plastic 402 can be introduced to affix the middle plate 302 to the middle frame 202. NMT may employ the capabilities of nanotechnology to integrate metals and plastics at the nanoscale level to create a strong bond between dissimilar materials. The NMT process can integrate the molding of hard plastics with metals, leading to the production of lightweight electronic device components. In some cases, a diverse range of metal materials, including but not limited to aluminum, iron, and stainless steel can be bonded to plastic materials such as polyphenylene sulfide (PPS), polybutylene terephthalate (PBT), nylon, or other polymers.

The illustrative examples recognize that electronic devices 102 with an all-metal casing can experience signal reduction due to the shielding effect of the metal whereas incorporating plastics can reduce the shielding effect since most plastics are non-conductive. The NMT process, therefore, combines the strengths of both materials and alleviates their individual drawbacks. The combined middle frame 202 and middle plate 302 therefore, form a chassis 106 that not only provides a desired metallic aesthetic but also provides a lightweight design for the electronic device 102. Similarly to the middle frame 202, the chassis 106 extends along the at least two opposed edges (204, 206). In some implementations, providing the middle frame 202 with the extra support plane of the middle plate 302 increases the thermal conductivity from 150 W/m-K to >3000 W/m-K. This increase allows heat from heat sources to diffuse more quickly and maintains the performance of the electronic device 102 under the action of rapid heat dissipation.

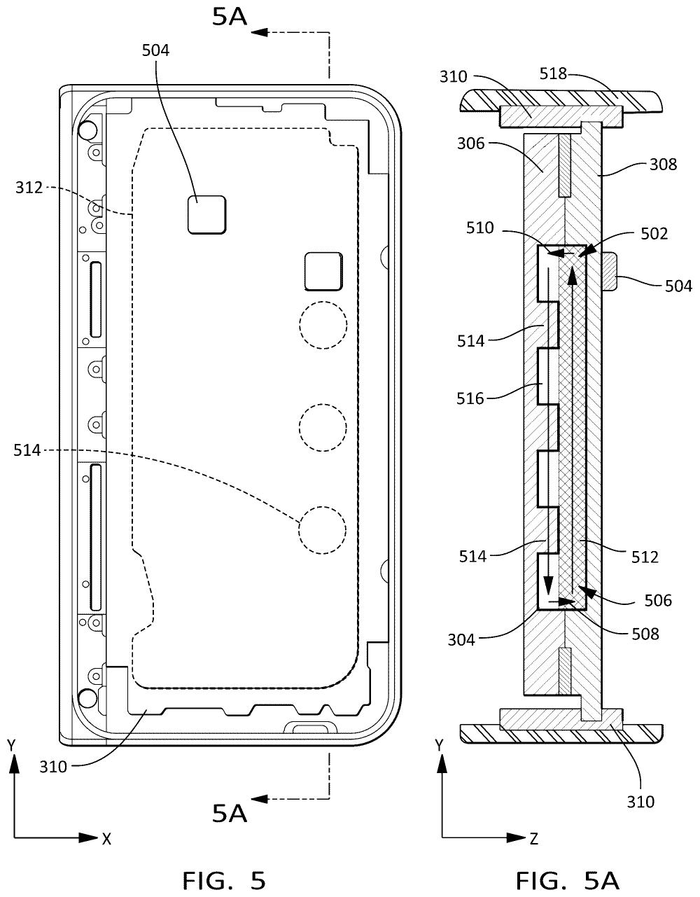

FIG. 5 illustrates the chassis 106 of the electronic device 102 showing a cross-section 5A (shown at FIG. 5A) and a vapor chamber 304 in accordance with an illustrative example.

The vapor chamber 304 comprises a first region 502 proximate to a heat source 504 and a second region 506 opposite the first region 502. A coolant 508 (e.g., a liquid coolant such as water), in a first mode of operation is configured to be evaporated into evaporated coolant 510 at the first region 502 by heat absorbed from the heat source 504, and in a second mode of operation is configured to be condensed in the second region 506.

The evaporation and condensation cause the coolant 508 to dissipate heat across the vapor chamber area 312. A coolant transmission material 512 is employed to transmit the coolant 508 that is condensed from the second region 506 to the first region 502. In some implementations, the coolant transmission material 512 is a wick structure that facilitates the movement of the coolant 508 through capillary action. This capillary action may occur due to the adhesion of the coolant molecules to the wick structure and the cohesion between the coolant molecules themselves. The wick structure may include a network of pores or channels that allow liquid to move therethrough.

As illustrated in FIG. 5, the top cover 306 may comprise a plurality of support pins 514 that fix the coolant transmission material 512 in place and constrain movement thereof. The support pins 514 maintain the gap or vapor cavity 516 inside the vapor chamber 304 and prevents the vapor chamber 304 from collapse onto itself. In some implementations, the support pins have an oval profile and thus have a minimal impact on the movement of the evaporated coolant 510. Upon generation of the evaporated coolant 510 at the first region 502, the evaporated coolant 510 passes through the vapor cavity 516, which is interspersed with the support pins 514, towards the second region 506 for condensation. The heat source 504 is illustrated in a particular portion, but can be in various places without ill effect on the heat dissipation by the vapor cavity 516. In some examples, the clamping structure 310 is held in place by a perimeter wall 518 of the middle frame 202. By virtue of the structure of the vapor chamber 304 described herein, the heat generated by the heat source is dissipated to other parts of the vapor chamber 304 that have comparatively less heat. The capillary action of the coolant transmission material 512 and coolant phase change/convection process and the high thermal conductivity of the top cover 306 and base member 308 of the middle plate 302 produce a combined effect of rapidly dissipating heat away from the heat sources.

In some implementations, by virtue of the volume conserving design, a total thickness of the middle plate (in the Z-axis) is from about 0.3 mm (e.g., 0.3-0.35 mm, or 0.25-0.4 mm, or 0.2-0.5 mm). Further, a total thickness of the base member 308 (in the Z-axis) is about 0.1 mm (e.g., 0.1-0.15 mm, or 0.05-0.25 mm).

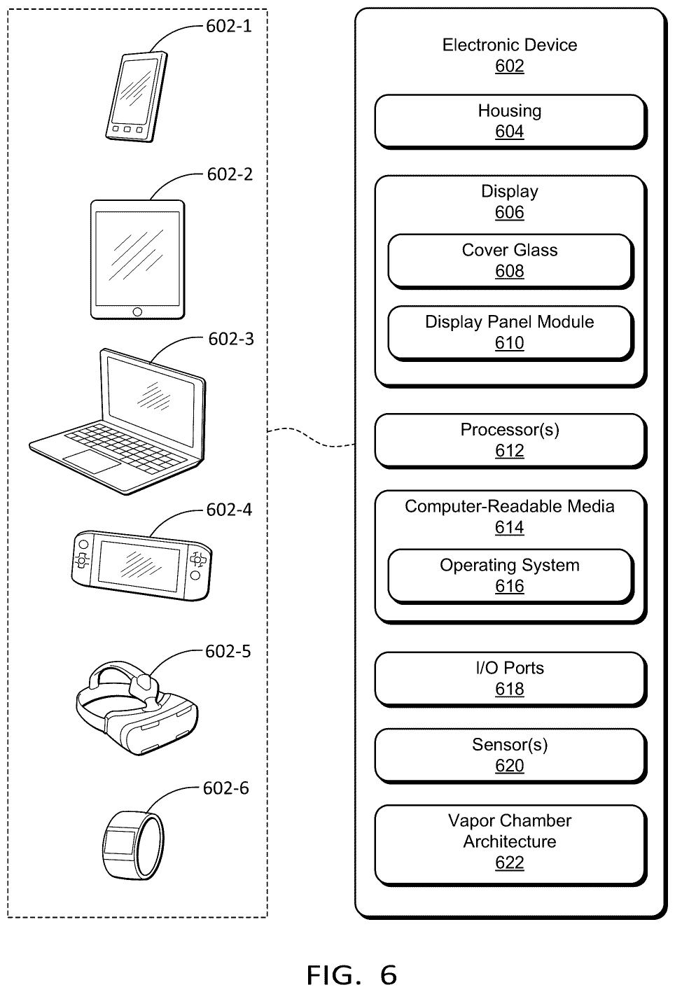

FIG. 6 illustrates an example device diagram of an example electronic device 602 (e.g., example electronic device 102) in which integrated vapor chamber architectures can be implemented. The electronic device 602 may include additional components and interfaces omitted from FIG. 6 for the sake of clarity.

The electronic device 602 can be any of a variety of consumer electronic devices. As non-limiting examples, the electronic device 602 can be a mobile phone 602-1, a tablet device 602-2, a laptop computer 602-3, a portable video game console 602-4, virtual-reality (VR) goggles 602-5, a computerized watch 602-6, and the like.

The electronic device 602 includes a housing 604 and a display 606 (e.g., the display 104), which define at least one internal cavity within which one or more of a plurality of electronic components may be disposed. In implementations, a middle frame may define one or more portions of the housing 604. As an example, a middle frame can include plastic or metallic walls that define portions of the housing 604. In additional implementations, a middle frame may support one or more portions of the housing 604. As an example, one or more exterior housing components (e.g., plastic panels) can be attached to the middle frame (e.g., a chassis). In so doing, the middle frame may physically support the one or more exterior housing components, which define portions of the housing 604. In implementations, the middle frame and/or the exterior housing components may be composed of crystalline or non-crystalline (e.g., metals, plastics) inorganic solids.

The display 606 may include a cover glass 608 and a display panel module 610. The cover glass 608 may be composed of a variety of transparent materials including polymers (e.g., plastic, acrylic), glass (e.g., tempered glass, ceramic glass, sapphire), and so forth, forming a three-dimensional shape. For example, the display 606 may be implemented as a plastic organic light-emitting diode (POLED) or as a glass organic light-emitting diode (GOLED). During manufacturing, a bottom face of the cover glass 608 may be bonded (e.g., glued) to the display panel module 610 to protect the display panel module 610 as well as to serve as a barrier to ingress contaminants (e.g., dust, water). The display 606 can include any suitable touch-sensitive display device, such as a touchscreen, a liquid crystal display (LCD), a thin-film transistor (TFT) LCD, an in-place switching (IPS) LCD, a capacitive touchscreen display, an organic light-emitting diode (OLED) display, an active-matrix organic light-emitting diode (AMOLED) display, a super AMOLED display, and so forth. The display 606 may be referred to as a display or a screen, such that digital content may be displayed on-screen.

The display panel module 610 may include a two-dimensional pixel array forming a grid, operably coupled to one or more row-line drivers via electrical traces. The pixel array generates light to create an image on the display 606 upon electrical activation by one or more drivers. As an example, data-line drivers provide voltage data via electrical traces to the pixel array to control a luminance of individual pixels. A section (e.g., a surface) of the display panel module 610 (e.g., a bottom section) may include more circuitry, such as electrical traces and drivers, than other portions of the display panel module 610 (e.g., a top section, a side section). In such a configuration, the display panel module 610 can be configured such that the section having more circuitry is folded or bent in a direction opposite to the cover glass 608. As a result, the display panel module 610 may include a display flex and/or a chip on flex subassembly.

The electronic device 602 may further include one or more processors 612. The processor(s) 612 can include, as non-limiting examples, a system on a chip (SoC), an application processor (AP), a central processing unit (CPU), or a graphics processing unit (GPU). The processor(s) 612 generally executes commands and processes utilized by the electronic device 602 and an operating system installed thereon. For example, the processor(s) 612 may perform operations to display graphics of the electronic device 602 on the display 606 and can perform other specific computational tasks.

The electronic device 602 may also include computer-readable storage media (CRM) 614. The CRM 614 may be a suitable storage device configured to store device data of the electronic device 602, user data, and multimedia data. The CRM 614 may store an operating system 616 that generally manages hardware and software resources (e.g., the applications) of the electronic device 602 and provides common services for applications stored on the CRM 614. The operating system 616 and the applications are generally executable by the processor(s) 612 to enable communications and user interaction with the electronic device 602. One or more processor(s) 612, such as a GPU, perform operations to display graphics of the electronic device 602 on the display 606 and can perform other specific computational tasks. The processor(s) 612 can be single-core or multiple-core processors.

The electronic device 602 may also include input/output (I/O) ports 618. The I/O ports 618 allow the electronic device 602 to interact with other devices or users. The I/O ports 618 may include any combination of internal or external ports, such as universal serial bus (USB) ports, audio ports, Serial ATA (SATA) ports, peripheral component interconnect express (PCIe) based ports or card-slots, secure digital input/output (SDIO) slots, and/or other legacy ports.

The electronic device 602 may further include one or more sensors 620. The sensor(s) 620 can include any of a variety of sensors, such as an audio sensor (e.g., a microphone), a touch-input sensor (e.g., a touchscreen), an image-capture device (e.g., a camera, video-camera), proximity sensors (e.g., capacitive sensors), an under-display fingerprint sensor, or an ambient light sensor (e.g., photodetector). In implementations, the electronic device 602 includes one or more of a front-facing sensor(s) and a rear-facing sensor(s).

The electronic device 602 may also include a vapor chamber architecture 622 (e.g., the vapor chamber 304) configured to rapidly dissipate heat from heat sources, such as one or more of the various processors, components, sensors, and displays described above, while reducing the overall thickness of the electronic device.

### CONCLUSION

Unless context dictates otherwise, use herein of the word “or” may be considered use of an “inclusive or,” or a term that permits inclusion or application of one or more items that are linked by the word “or”. Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying Drawings and terms discussed herein may be indicative of one or more items or terms, and thus reference may be made interchangeably to single or plural forms of the items and terms in this written description.

Although aspects of an integrated vapor chamber are described herein with various examples, it is to be understood that the subject of the appended claims is not necessarily limited to the specific techniques, systems, and/or apparatuses described. Further, various different aspects are described, and it is to be appreciated that each described aspect can be implemented independently or in connection with one or more other described aspects.

What is claimed is:

1. An electronic device comprising:
a middle frame extending along at least two opposed edges, the middle frame configured to provide mechanical support for the electronic device;
a middle plate affixed to the middle frame to define an inner layer of a chassis, the middle plate including a base member extending to a perimeter wall of the middle frame and including a well; and
a vapor chamber including the well and disposed inside the middle plate, the vapor chamber comprising:
a first region proximate to a heat source and a second region spaced from the first region; and
a coolant, which in a first mode of operation is configured to be evaporated at the first region by heat absorbed from the heat source, and which in a second mode of operation is configured to be condensed in the second region.

2. The electronic device of claim 1, wherein the vapor chamber further comprises a coolant transmission material positioned at least partially in the well that transmits, from the second region to the first region, the coolant that is condensed.

3. The electronic device of claim 2, wherein the top cover includes a plurality of support pins configured to fixedly constrain the coolant transmission material.

4. The electronic device of claim 2, wherein the coolant transmission material is a wick.

5. The electronic device of claim 1, wherein the middle plate comprises at least a top cover and the base member configured to encase the vapor chamber.

6. The electronic device of claim 1, wherein the vapor chamber further comprises:
a vapor cavity configured to transport, in the first mode, the evaporated coolant from the first region to the second region.

7. The electronic device of claim 1, wherein the middle frame and middle plate form the chassis, the chassis being configured to encase at least a plurality of device components.

8. The electronic device of claim 1, wherein the middle plate comprises a high-thermal-conductivity metal material.

9. The electronic device of claim 8, wherein the high-thermal-conductivity metal material is stainless steel or titanium.

10. The electronic device of claim 1, wherein a total thickness of the middle plate is from 0.3-0.35 mm.

11. The electronic device of claim 1, wherein the middle frame and the middle plate are affixed together with a plastic via nano injection molding.
